(19) United States
(12) Patent Application Publication
(10) Pub. No.: US 2009/0096037 A1
(43) Pub. Date: Apr. 16, 2009

(54) SEMICONDUCTOR DEVICE HAVING RECESSED FIELD REGION AND FABRICATION METHOD THEREOF

(75) Inventors: Ji-Hye YI, Gyeonggi-do (KR); Hwa-Sung RHEE, Gyeonggi-do (KR); Ho LEE, Chungcheongnam-do (KR); Myung-Sun KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/248,593

(22) Filed: Oct. 9, 2008

(30) Foreign Application Priority Data
Oct. 10, 2007 (KR) 2007-0102151

(51) Int. Cl. H01L 29/78

(52) U.S. Cl. 257/396; 257/409; 257/E29.255

(57) ABSTRACT

A semiconductor device including an active region formed on a semiconductor substrate, and a field region adjacent to the active region, which is able to increase a width of the active region through use of a field recess portion at one surface side of the field region. The field recess portion may be laterally adjacent to a portion of the active region, thereby resulting in an increase of a width of the active region. A gate insulating film and a gate electrode may be formed on the field region and the active region, the gate insulating film and the gate electrode being formed in the field recess portion. The width of the active region may be a channel width.

### CROSS-REFERENCE TO RELATED PATENT APPLICATION

This application claims the benefit of Korean Patent Application No. 10-2007-0102151, filed on Oct. 10, 2007, in the Korean Intellectual Property Office, the disclosure of which is incorporated herein in its entirety by reference.

### BACKGROUND OF THE INVENTION

1. Field of the Invention

The present invention relates to a semiconductor device and a fabrication method thereof, and more particularly, to a semiconductor device having an increased channel width and a fabrication method thereof.

2. Description of the Related Art

Decreasing power consumption of integrated circuits corresponds to speed enhancements and a rapid decrease in the size of the integrated circuits. Accordingly, a channel length and a channel width of a semiconductor device, i.e., a metal oxide semiconductor (MOS) transistor, for use in the semiconductor integrated circuit have been decreasing over time.

If the semiconductor device channel length is decreased, a short channel effect (SCE) is produced, which is an undesirable electrical characteristic. If the channel width is decreased, the current characteristic of a semiconductor device deteriorates. In order to prevent SCE, a shallow junction forming thin junctions of source/drain are required, as well as a decrease of the transistor channel length in a horizontal direction.

However, no specific method has been previously suggested that prevents a deterioration of current characteristic by a decrease in the channel width. Accordingly, a need remains for a semiconductor device and a fabrication method thereof that can increase a channel width even if the size of the integrated semiconductor circuit is decreased.

### SUMMARY OF THE INVENTION

The present invention provides a semiconductor device of increased channel width to satisfy a requirement of the technical field belonged to the present invention.

The present invention also provides a fabrication method of a semiconductor conveniently increasing a channel width.

According to an aspect of the present invention, there is provided a semiconductor device including an active region formed on a semiconductor substrate, a field region adjacent to the active region, and a field recess portion at one surface side of the field region, the field recess portion being laterally adjacent to a portion of the active region, thereby resulting in an increase of a width of the active region. A gate insulating film and a gate electrode may be formed on the field region and the active region, the gate insulating film and the gate electrode being formed in the field recess portion. The width of the active region may be a channel width. The field recess portion may be formed on each laterally adjacent side of the portion of the active region. The width of the active region prior to the field recess portion being formed may correspond to W₁. A width W₂ of the active region may correspond to the increase of the width of the active region due to the field recess portion. The increased width of the active region may be twice a width W₂.

According to another aspect of the present invention, there is provided a semiconductor substrate including a first region and a second region, a first active region formed in the first region and a second active region formed in the second region of the semiconductor substrate, a first field region formed in the first region, at least one field recess portion formed in the first field region, the at least one field recess portion being laterally adjacent to a portion of the first active region, thereby resulting in an increase of a width of the first active region. A second field region may be formed in the second region, which does not have a field recess portion to increase a width of the second active region. A gate insulating film and a gate electrode may be formed on the first field region, the second field region, the first active region, and the second active region. The width of the active region of the first region may be a channel width. The width of the first active region prior to the field recess portion being formed may correspond to W₁. A width W₂ of the first active region may correspond to the increase of the width of the first active region due to the field recess portion. The increased width of the first active region may be twice a width W₂.

According to another aspect of the present invention, there is provided a method of fabricating a semiconductor device including forming a field region and an active region on a semiconductor substrate, and implanting an impurity for field recess into opposite surface parts of the field region. A field recess portion is formed at the opposite surface parts of the field region and a gate insulating film and a gate electrode are formed on the field region having a part of the field recess portion and on the active region.

Implanting an impurity for well and an impurity for channel into the active region of the semiconductor substrate may be further included. Activation annealing of the impurity for well and the impurity of channel may be further included after the implanting the impurity for well and the impurity for channel. The implanting the impurity for field recess may be performed before or after the activation annealing of the impurity for well and the impurity for channel. The implanting the impurity for field recess may be performed using nitrogen or fluorine.

The field recess portion may be formed through cleaning the semiconductor having the field region implanted with the impurity for field recess. A depth of the field recess portion may be controlled by varying rate and amount of etching the field region implanted with the impurity for field recess through a dose and energy of the impurity, or kind and concentration of cleaning solution.

According to another aspect of the present invention, there is provided a method of fabricating a semiconductor device including forming a field region and an active region on a semiconductor substrate having a first region and a second region, and selectively implanting an impurity for field recess into opposite surface parts of the field region of the first region. A field recess portion is formed at the opposite surface parts of the field region of the first region. A gate insulating film and a gate electrode are formed on the field region having a part of the field recess portion of the first region, on the field region of the second region of the semiconductor substrate and on the active region.

The implanting the impurity for the field recess may be performed using nitrogen or fluorine. The field recess portion may be formed through cleaning the semiconductor substrate by using an etch rate difference between the filed regions where the impurity for the field recess is implanted or not.

According to another aspect of the present invention, there is provided a method of fabricating a semiconductor device including forming a plurality of active regions formed in a channel length direction on a semiconductor substrate and separated from each other in a channel width direction perpendicular to the channel length direction by field regions. An impurity for field recess is implanted on one part of the field regions in the channel width direction. A field recess portion is formed in the channel width direction by using an etch rate difference between the filed regions where the impurity for the field recess is implanted or not. A plurality of gate lines are formed in the channel width direction on the field regions including the field recess portion and the active regions and separated in the channel length direction while crossing perpendicular to the active regions.

Implanting the impurity for field recess may be performed using nitrogen or fluorine. A width of the active regions in the channel width direction may be increased by the field recess portion.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view illustrating a semiconductor device according to an embodiment of the present invention;

FIG. 2 and FIG. 3 are cross-sectional views taken along line A-A′ of FIG. 1;

FIG. 4 is a plan view illustrating a semiconductor device according to another embodiment of the present invention;

FIG. 5 through FIG. 9 are cross-sectional views taken along line A-A′ of FIG. 4 illustrating a method of fabricating the semiconductor according to an embodiment of the present invention;

FIG. 10 is a graph illustrating an increased length of a channel width dependent on dose of an impurity for field recess according to an embodiment of the present invention; and

FIG. 11 and FIG. 12 are graphs illustrating a relation of on-current (Iₒₙ) dependent on off-current (I_{off}) of a semiconductor device according to an embodiment of the present invention.

### DETAILED DESCRIPTION OF THE INVENTION

A semiconductor device according to example embodiments of the present invention increases a width of the active region by providing a field recess portion at one surface of a field region adjacent to an active region. That is, a channel width of a semiconductor device according to example embodiments of the present invention is increased by disposing more active region through recessing at a surface part of a field region laterally adjacent to a portion of the active region. The field recess portion is formed, for example, during a cleaning process before forming a gate insulating film, but after implanting an impurity unaffecting semiconductor device operation using a mask pattern during a semiconductor device fabricating processes. Accordingly, the semiconductor device according to example embodiments of the present invention can easily increase the channel width without performing a specific mask process.

The above features and advantages of the present invention and a method of achieving them will become more apparent by referring to described exemplary embodiments with the attached drawings. This invention may, however, be embodied in many different forms and should not be construed as being limited to the embodiments set forth herein. These embodiments are only provided so that this disclosure will be thorough and complete to fully convey the scope of the invention to those skilled in the art, and the present invention is only defined by the scope of claims. Accordingly, well known processes and device structures are not specifically described in order to prevent obscure interpretation. Each embodiment described here includes its complementary embodiment. Like numbers refer to like elements throughout the specification.

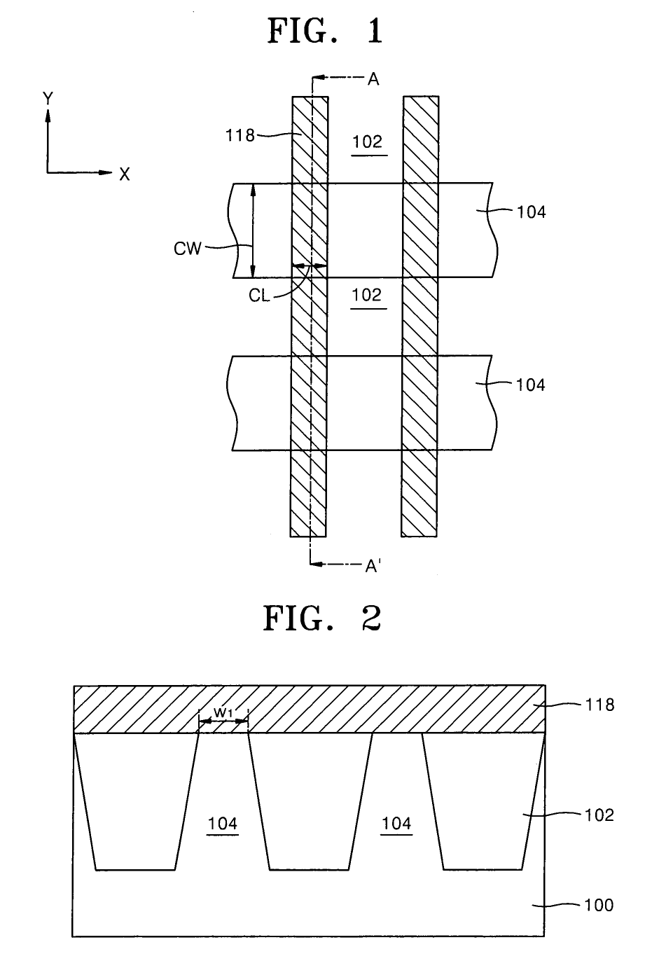

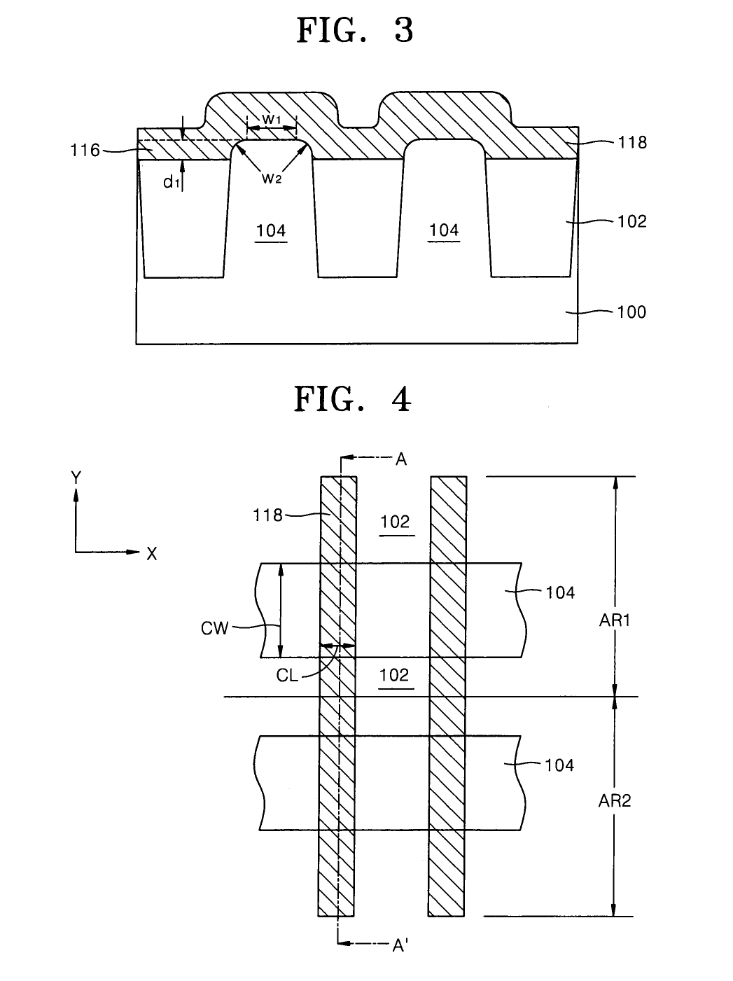

FIG. 1 is a plan view illustrating a semiconductor device according to an embodiment of the present invention. Specifically, active regions 104 may be formed in a channel length direction (X direction) on a semiconductor substrate (e.g., substrate 100 in FIG. 2 and FIG. 3). The semiconductor substrate may be, for example, a silicon substrate. Active regions 104 may be separated in a channel width direction (Y direction) perpendicular to the channel length direction by field regions 102.

Gate lines 1 18 (gate electrodes) may be formed on the active regions 104 and the field regions 102 in the channel width direction crossing perpendicular to the active regions 104. A gate insulating film (not shown) may be disposed on the gate lines 118. The gate lines 118 may be separated from each other in the channel length direction. As a result, at least one metal oxide semiconductor (MOS) transistor may be formed at a crossed region where the active regions 104 and the gate lines 118 are crossed. The MOS transistor includes channel length CL and channel width CW. According to an embodiment of the present invention, CL may be about 40 to 45 nanometers (nm) and CW may be about 300 to 500 nm.

FIG. 2 and FIG. 3 are cross-sectional views taken along line A-A′ of FIG. 1. As shown in FIG. 2 and FIG. 3, the semiconductor substrate 100 may be formed to include the field regions 102. The active regions 104 may be defined by the field regions 102. The field regions 102 are formed as a trench structure, for example, a shallow trench isolation (STI) region buried with oxide film.

As shown in FIG. 3, a field recess portion 116 may be formed at one surface side of the field region 102 laterally adjacent to a portion of the active region 104. That is, a field recess portion 116 may be formed at a surface part of one side of the field region 102 laterally adjacent to a portion of the active region 104. The recess portion 116 is a portion formed recessed from a surface of the active region 104 by a certain depth d, in the channel width direction, which by comparison is not present in FIG. 2. The recess portion 116 may be formed on each laterally adjacent side of the portion of the active region 104. Accordingly, the channel width CW in FIG. 3 is increased through expansion of the active regions 104 by the field recess portion 116. That is, the channel width CW (the width of the active regions 104) in FIG. 3 may be increased to about W₁+2W₂, or in other words, the CW may be increased by as much as 2W₂. By comparison, the channel width (the width of the active regions) in FIG. 2 is W₁.

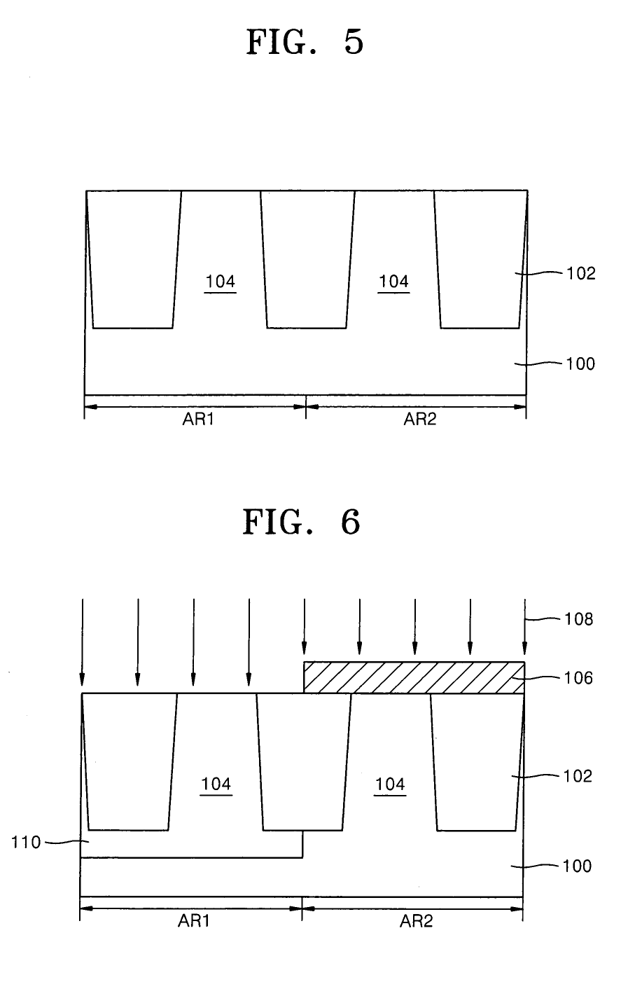

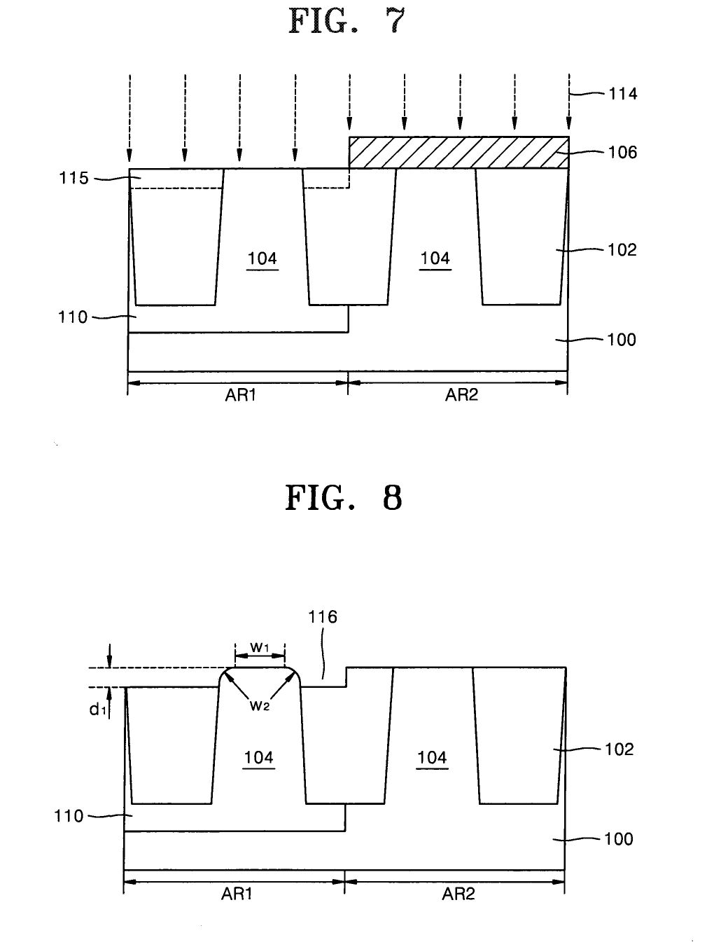

FIG. 4 is a plan view illustrating a semiconductor device according to another embodiment of the present invention. FIG. 5 through FIG. 9 are cross-sectional views taken along line A-A′ of FIG. 4 illustrating a method of fabricating the semiconductor according to an embodiment of the present invention.

Specifically, FIG. 4 is substantially the same as FIG. 1 except that a semiconductor substrate 100 is divided to a first region AR1 and a second region AR2. Next, a fabrication method of the semiconductor device according to the present invention is described with reference to FIG. 5 through FIG. 9. The semiconductor substrate 100, which is divided into the two regions is described for convenience' sake in FIG. 5 through FIG. 9.

Referring to FIG. 5, a field region 102 and an active region 104 are formed on the semiconductor substrate 100, for example, silicon substrate divided by the first region AR1 and the second region AR2. The field region 102 may be formed by burying insulate film such as an oxide film in a trench after forming the trench in the semiconductor substrate 100. Though a shallow trench isolation STI region is formed for the field region 102 in the present embodiment, other regions may be formed such as through a field oxide film by local oxidation of silicon (LOCOS) method.

Referring to FIG. 6, a mask pattern 106 may be formed on the second region AR2 of the semiconductor substrate 100. In other words, the active region 104 and the field region of the second region AR2 may be covered with the mask pattern 106. The mask pattern 106 may be formed with photo resist pattern. An impurity 108 for the well and channel may be implanted with the mask pattern 106 as mask. Accordingly, a well region 110 is formed in the first region AR1 and the impurity for the channel (not shown) is implanted into the active region 104 in the first region AR1.

The well region 110 may be p-well or n-well. Boron may be used for the impurity for the well when the well region 110 is a p-well and Arsenic or phosphorous may be used for the impurity for the well when the well region 110 is a n-well. The impurity for the channel may use Arsenic and Phosphorous, or Boron dependent on a form of MOS transistor, i.e., whether p-type MOS or n-type MOS.

Referring to FIG. 7, an impurity 114 for field recess is selectively implanted again into the first region AR1 with the mask pattern 106 as mask. That is, the impurity 114 for field recess, which is selectively implanted into the first region AR1 damages a particular portion of the field region 102. Fluorine F, Nitrogen N, or nitrogen molecules may be used for the impurity 114 for field recess. An implanting amount of the impurity for field recess 114, i.e., a dose, may be approximately between 5E13/cm² and 5E15/cm².

Accordingly, a field recess impurity region 115 may be formed in the field region 102 of the first region AR1 exposed by the mask pattern 106. Next, activation annealing of the impurities for well, channel, and field recess may be performed. Implanting of the impurity 114 for field recess may be performed after the activation annealing as necessary. Or the activation annealing may be performed after the implanting of the impurity 114 for field recess. The implanting of the impurity 114 for field recess may be performed as long as the implanting of the impurity 114 for field recess is performed before a cleaning process of a gate insulating film.

Even if the impurity 114 for field recess is implanted into the active region 104, it does not affect the semiconductor device operation. Particularly, when Fluorine F is used for the impurity 114 for field recess, silicon-hydrogen (Si—H) bonds are changed to strong silicon fluorine (Si—F) bonds, thereby enhancing a reliability of the gate insulating film. Further, a depth of the field recess impurity region 115 formed afterwards may be controlled if an implant energy and a dose of the impurity 114 for field recess are adjusted.

The mask pattern 106 used for the impurities 108 for well and channel may be used also when implanting the impurity 114 for field recess. The field recess impurity region 115 may be formed without an additional photo process when fabricating example embodiments of the semiconductor device of the present invention.

Referring to FIG. 8, the mask pattern 106 is removed. Then, the semiconductor substrate 100, which is formed with the field recess impurity region 115, may be cleaned. Cleaning employs a cleaning process which is used at a time before forming the gate insulating film, for example, an oxide film, when fabricating the semiconductor device. Mixture solution of hydro fluorine (HF) solution and SCI (mixture of NH₄OH, H₂O₂ and H₂O) solution may be used for the semiconductor substrate 100 formed with the field recess impurity region 115. Then, the field recess portion 116 may be formed selectively on the first region AR1 in a channel width direction using a difference in etch rate, for example, wet etch rate, between the field recess impurity region 115 and the other regions.

Particularly, the etch rate is usually increased in the field recess impurity region 115. In other words, the field recess portion 116 of example embodiments of the present invention may be formed using the difference of etch selectivity between the field recess impurity region 115 and the other region, that is, the field region 102 of the second region AR2. In other words, the field recess portion 116 is formed in the field region 102 of the first region AR1, i.e., on each laterally adjacent side of an upper portion of the active region 104, but the field recess portion 116 is not formed in the field region 102 of the second region AR2. A depth of the field recess portion 116 may be controlled through varying rate and amount of etching the field region 102 implanted with the impurity for field recess 114 by dose and energy of the impurity, or kind and concentration of a cleaning solution.

A depth of the field recess portion 116 formed using the difference in etch rate is indicated by d₁ as before. Accordingly, the channel width of the first region becomes W₁+2W₂ for an embodiment of the semiconductor device. That is, the channel width by the field recess portion 116 may be increased by as much as 2W₂.

According the present embodiment, depth d₁ of the field recess portion 116 may be formed approximately 20 to 60 nm deep. The increased portion 2W₂ of the channel width is approximately 40 to 120 nm. If the channel width W₁ without recess is designed to be between 300 to 500 nm, the increased channel width portion 2W₂ significantly widens the channel width W₁. According to the present embodiment, the increased channel width portion 2W₂ results in an increase of the channel width by approximately 8% to 40% of the channel width W₁.

The recessed portion 116 may be formed in the first region AR1 with uniform depth. However, the field recess portions of different depth from each other may be formed in the first region AR1 if the impurity 114 for field recess is implanted by using a mask pattern and/or by changing ion implant energy or dose. In this way, the field recess portion 116 may be formed with different depths in respective regions. Accordingly, example embodiments of the present invention may be employed advantageously when integrating the various MOS transistors in one semiconductor device.

Further, since example embodiments of the present invention additionally implant the impurity 114 for field recess and use the cleaning process after implanting the impurities 108 for the well and channel when forming the field recess portion 116, the channel width can be easily increased without a separate process such as a dry etch process.

Referring to FIG. 9, the gate insulating film (not shown) and a gate electrode 118 (gate line) are formed on a front surface of the semiconductor substrate 100 elevated along the channel width. The gate electrode 118 is completed through patterning process. The semiconductor device is usually completed by implanting impurities for source and drain (not shown) after forming the gate electrode 118.

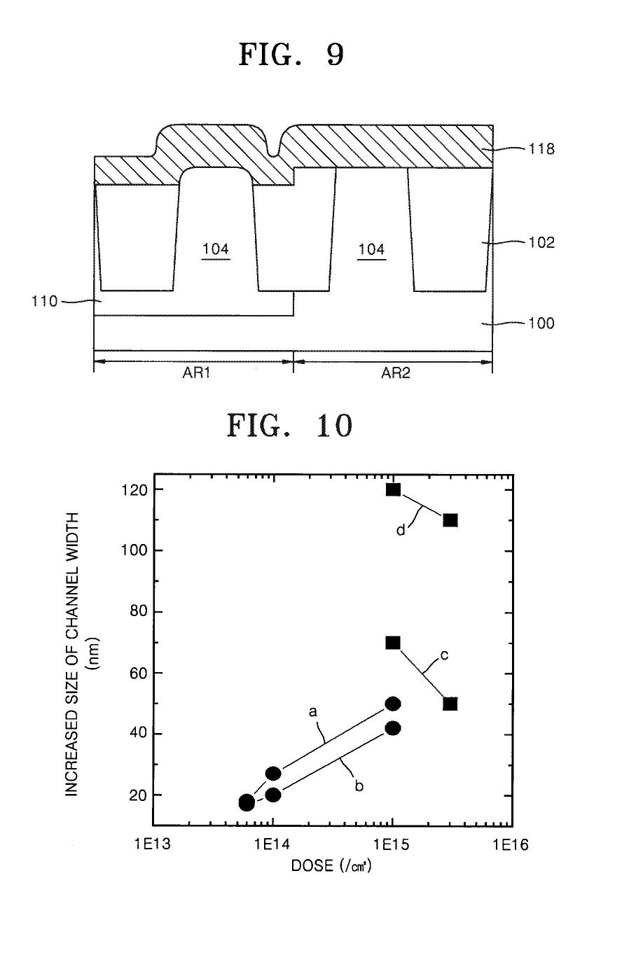

FIG. 10 is a graph illustrating the increased size of the channel width dependent on dose of an impurity within the field recess region 115 according to an embodiment of the present invention. Specifically, FIG. 10 illustrates electrically sampled data showing the size of the increased channel width dependent on dose of the impurity for field recess. Reference marks ‘a’ and ‘b’ used Nitrogen as the impurity for field recess where ‘a’ is related to p-metal oxide silicon field effect transistor (MOSFET) and ‘b’ is related to n-MOSFET. Reference marks ‘c’ and ‘d’ used Fluorine as the impurity for field recess where ‘c’ is related to n-MOSFET and ‘d’ is related to p-MOSFET.

As shown in FIG. 10, the size of the channel width is increased as the dose increases when implanted with Nitrogen (‘a’, ‘b’), whereas the size of the channel width is decreased as the dose increases when implanted with fluorine (‘c’, ‘d’).

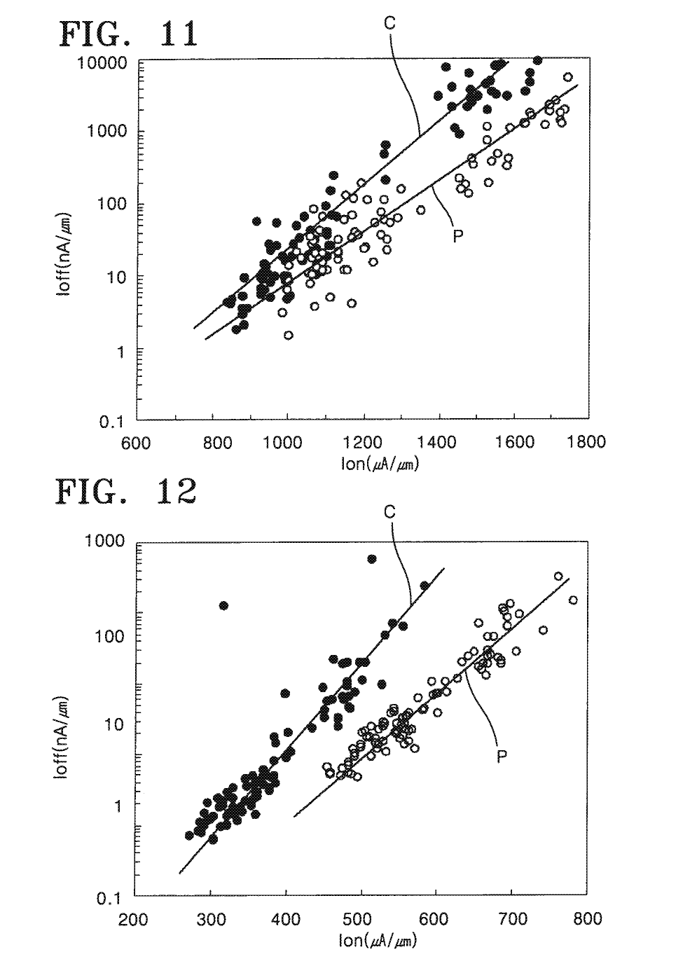

FIG. 11 and FIG. 12 are graphs illustrating a relation of on-current (Iₒₙ) dependent on off-current (I_{off}) of a semiconductor device according to an embodiment of the present invention. Specifically, FIG. 11 is related to a n-MOSFET device and FIG. 12 is related to a p-MOSFET device. In FIG. 11 and FIG. 12, reference mark ‘C’ represented as • is related to an example for comparison without implanting the impurity for field recess and reference mark ‘P’ represented as ◯ is related to an embodiment according to the present invention implanted with the impurity for field recess. As described before, the dose is approximately between 5E13/cm² and 5E15/cm².

As shown in FIG. 11 and FIG. 12, the Iₒₙ, current is increased when implanted with the impurity for field recess without a decrease in the I_{off} current characteristic. In more detail, when the I_{off} current in an n-MOSFET device is about 10 nA/μm, the Iₒₙ, current for devices implanted with the impurity for field recess is about 1100 μA/μm whereas a device without the field recess implantation has an Iₒₙ current of only about 950 μA/μm. Also, when the I_{off} current in a p-MOSFET device is about 10 μA/μm, the Iₒₙ current of a device implanted with the impurity for field recess is about 500 μA/μm whereas a device without the filed recess implantation has an Iₒₙ current of only about 400 μA/μm. Accordingly, it has been empirically shown that the Iₒₙ current due to the increased channel width when the impurity for field recess is implanted can increase Iₒₙ current without deteriorating an I_{off} current characteristic. Particularly, since the field recess size is increased more in the p-MOSFET than in the n-MOSFET, an increased amount of Iₒₙ is larger in p-MOSFET than in the n-MOSFET.

As described above, the semiconductor device according to the present invention increases the width of the active region through providing the field recess portion at one surface side of the field region laterally adjacent to a portion of the active region. The current characteristics of the semiconductor device can be enhanced when the width of the channel is increased. Particularly, the recess portion is conveniently formed through implanting the impurity for field recess not affecting the device operation characteristic at one surface side of the field region laterally adjacent to the portion of the active region and using the cleaning process performed before forming gate insulating film. The depth of the field recess portion may be controlled by using dose and energy of the impurity for field recess, or kind and concentration of cleaning solution. Further, the field recess portion may be formed with different depths in respective regions. Accordingly, the present invention may be employed advantageously when integrating the various MOS transistors in one semiconductor device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
an active region formed on a semiconductor substrate;
a field region adjacent to the active region; and
a field recess portion at one surface side of the field region, the field recess portion being laterally adjacent to a portion of the active region, thereby resulting in an increase of a width of the active region.

2. The semiconductor device of claim 1, further comprising:
a gate insulating film and a gate electrode formed on the field region and the active region, the gate insulating film and the gate electrode being formed in the field recess portion.

3. The semiconductor device of claim 1, wherein the width of the active region is a channel width.

4. The semiconductor device of claim 1, wherein the field recess portion is formed on each laterally adjacent side of the portion of the active region, wherein the width of the active region prior to the field recess portion being formed corresponds to W₁, wherein a width W₂ of the active region corresponds to the increase of the width of the active region due to the field recess portion, and wherein the increased width of the active region is twice a width W₂.

5. A semiconductor device comprising:
a semiconductor substrate including a first region and a second region;
a first active region formed in the first region and a second active region formed in the second region of the semiconductor substrate;
a first field region formed in the first region;
at least one field recess portion formed in the first field region, the at least one field recess portion being laterally adjacent to a portion of the first active region, thereby resulting in an increase of a width of the first active region;
a second field region formed in the second region, which does not have a field recess portion to increase a width of the second active region; and
a gate insulating film and a gate electrode formed on the first field region, the second field region, the first active region, and the second active region.

6. The semiconductor device of claim 5, wherein the width of the first active region is a channel width.

7. The semiconductor device of claim 5, wherein the at least one field recess portion is formed on each laterally adjacent side of the portion of the first active region.

8. The semiconductor device of claim 7, wherein the width of the first active region prior to the at least one field recess portion being formed corresponds to W₁, and wherein a width W₂ of the first active region corresponds to the increase of the width of the first active region due to the at least one field recess portion.

9. The semiconductor device of claim 8, wherein the increased width of the first active region is twice a width W₂.

10. A semiconductor device comprising:
a semiconductor substrate;
a plurality of active regions disposed in a channel length direction on the semiconductor substrate and separated from each other in a channel width direction perpendicular to the channel length direction by field regions;
a plurality of field recess portions, each field recess portion being formed at one surface side of at least one of the field regions and laterally adjacent to at least one of the active regions; and
a plurality of gate lines disposed in the channel width direction on at least some of the field regions, the field recess portions, and the active regions, the plurality of gate lines being perpendicular to the active regions.

11. The semiconductor device of claim 10, wherein at least one of the field recess portions is laterally adjacent to a portion of at least one of the active regions.

12. The semiconductor device of claim 11, wherein each field recess portion is laterally adjacent to a portion of at least one of the active regions.

13. The semiconductor device of claim 12, wherein each field recess portion is etched at one surface side of each of the field regions.

14. The semiconductor device of claim 10, wherein the field recess portions are formed according to an etch rate difference between the field regions, wherein the etch rate difference depends on whether or not an impurity for field recess is implanted or not in each of the field regions.

15. The semiconductor device of claim 10, wherein the field recess portions are formed using an impurity for field recess including one of nitrogen and fluorine.

16. The semiconductor device of claim 10, wherein the field recess portions increase a width of an upper portion of at least one of the active regions.

17. The semiconductor device of claim 10, wherein the semiconductor substrate includes a first region and a second region, a first active region formed in the first region and a second active region formed in the second region of the semiconductor substrate.

18. The semiconductor device of claim 17, further comprising:
a field recess portion at one surface side of a first field region, the field recess portion being laterally adjacent to a portion of the first active region, thereby resulting in an increase of a width of the first active region.

19. The semiconductor device of claim 18, further comprising:
a second field region, which does not have a field recess portion to increase a width of the second active region.

20. The semiconductor device of claim 19, wherein the plurality of gate lines are disposed on at least some of the first field region, the second field region, the first active region, and the second active region.
